(19) United States
(12) Patent Application Publication
(10) Pub. No.: US 2007/0141272 A1
(43) Pub. Date: Jun. 21, 2007

(54) Methods and apparatus for coating gas turbine components

(75) Inventors: Matthew David Saylor, Blanchester, OH (US); Nripendra N. Das, West Chester, OH (US); Brian Pilsner, Mason, OH (US); David Budinger, Loveland, OH (US); Bhupendra K. Gupta, Cincinnati, OH (US)

Correspondence Address: JOHN S. BEULICK (12729);C/O ARMSTRONG TEASDALE LLP, ONE METROPOLITAN SQUARE, SUITE 2600, ST. LOUIS, MO, 63102-2740, US

(73) Assignee: General Electric Company

(21) Appl. No.: 11/305,930

(22) Filed: Dec. 19, 2005

(51) Int. Cl. C08J 7/18; C23C 16/00

(52) U.S. Cl. 427/553; 118/723 MW

(57) ABSTRACT

Methods and apparatus for forming a metal coating on a surface of a workpiece are provided. The method includes positioning the workpiece in a microwavable chamber, positioning a coating material in the microwavable chamber, and heating at least the workpiece and the coating material using microwave range electromagnetic energy such that a diffusion coating of the coating material is formed on the surface of the workpiece.

### BACKGROUND OF THE INVENTION

This invention relates generally to gas turbine engines, and more particularly, to methods of depositing protective coatings on components of gas turbine engines.

Gas turbine engines typically include high and low pressure compressors, a combustor, and at least one turbine. The compressors compress air which is mixed with fuel and channeled to the combustor. The mixture is then ignited for generating hot combustion gases, and the combustion gases are channeled to the turbine which extracts energy from the combustion gases for powering the compressor, as well as producing useful work to propel an aircraft in flight or to power a load, such as an electrical generator.

The operating environment within a gas turbine engine is both thermally and chemically hostile. Significant advances in high temperature alloys have been achieved through the formulation of iron, nickel, and cobalt-base superalloys, though components formed from such alloys often cannot withstand long service exposures if located in certain sections of a gas turbine engine, such as the turbine, combustor and augmentor. A common solution is to provide turbine, combustor and augmentor components with an environmental coating that inhibits oxidation and hot corrosion.

Coating materials that have found wide use as environmental coatings include diffusion aluminide coatings, which are generally single-layer oxidation-resistant layers formed by a diffusion process, such as pack cementation. Diffusion processes generally include reacting the surface of a component with an aluminum-containing gas composition to form two distinct zones, the outermost of which is an additive layer containing an environmentally-resistant intermetallic comprising iron, nickel, or cobalt, depending on the substrate material. Beneath the additive layer is a diffusion zone that includes various intermetallic and metastable phases that form during the coating reaction as a result of diffusion gradients and changes in elemental solubility in the local region of the substrate. During high temperature exposure in air, the intermetallic forms a protective aluminum oxide (alumina) scale or layer that inhibits oxidation of the diffusion coating and the underlying substrate.

At least some known diffusion coatings are produced by thermal/chemical reaction process that takes place in a reduced and/or inert atmosphere at a predetermined temperature. Components are typically processed in a 2100 Fahrenheit or greater furnace by means of electric (resistive heating elements), plasma arc lamps or gas heating. These heating sources are not efficient and require extended heat ramp times to reach required dwell temperatures.

### BRIEF DESCRIPTION OF THE INVENTION

In one embodiment, a method for forming a metal coating on a surface of a workpiece includes positioning the workpiece in a microwavable chamber, positioning a coating material in the microwavable chamber, and heating at least the workpiece and the coating material using microwave range electromagnetic energy such that a diffusion coating of the coating material is formed on the surface of the workpiece.

In another embodiment, a method for forming a metal coating on surfaces of a turbine blade or other gas turbine component is provided. The turbine blade includes an outer surface and at least one internal passage. The method includes positioning the turbine blade in a microwavable chamber, positioning a coating material in the microwavable chamber, introducing an atmosphere that is at least one of inert and reducing to the chamber, and heating at least the turbine blade and the coating material using microwave range electromagnetic energy such that a diffusion coating of the coating material is formed on at least one of the outer surface and the at least one internal passage.

In yet another embodiment, a diffusion deposition chamber configured to form a metal coating on surfaces of a turbine blade is provided. The turbine blade includes an outer surface and at least one internal passage. The diffusion deposition chamber includes an insulated chamber configured to substantially prevent leakage of microwave energy from the chamber to an ambient space surrounding said chamber, and a source of microwave energy configured to heat a metallic object in the chamber substantially uniformly to a temperature of approximately 2100 degrees Fahrenheit.

### BRIEF DESCRIPTION OF THE DRAWINGS

FIG. 1 is schematic illustration of a gas turbine engine;

FIG. 2 is a perspective schematic illustration of a turbine rotor blade that may be used with gas turbine engine 10 shown in FIG. 1;

FIG. 3 is an internal schematic illustration of the turbine rotor blade shown in FIG. 2;

FIG. 4 is a flow chart of an exemplary method of forming a metal coating on a surface of a workpiece; and

FIG. 5 is a perspective view of a diffusion deposition chamber that may be used to perform the method illustrated in FIG. 4.

### DETAILED DESCRIPTION OF THE INVENTION

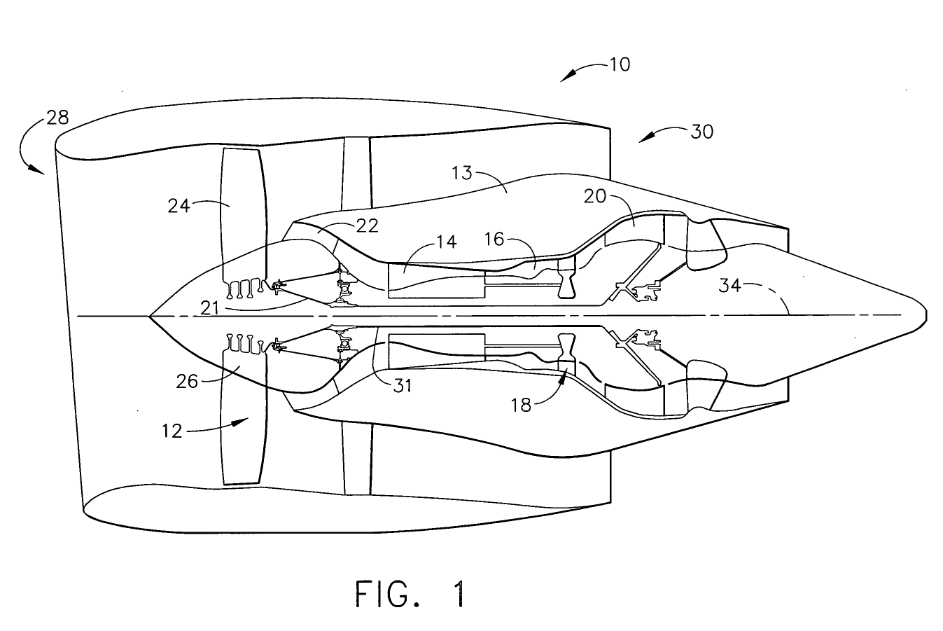

FIG. 1 is a schematic illustration of a gas turbine engine 10 that includes a fan assembly 12 and a core engine 13 including a high pressure compressor 14, and a combustor 16. Engine 10 also includes a high pressure turbine 18, a low pressure turbine 20, and a booster 22. Fan assembly 12 includes an array of fan blades 24 extending radially outward from a rotor disc 26. Engine 10 has an intake side 28 and an exhaust side 30. In one embodiment, the gas turbine engine is a GE90 available from General Electric Company, Cincinnati, Ohio. Fan assembly 12 and turbine 20 are coupled by a first rotor shaft 31, and compressor 14 and turbine 18 are coupled by a second rotor shaft 32.

During operation, air flows through fan assembly 12, along a central axis 34, and compressed air is supplied to high pressure compressor 14. The highly compressed air is delivered to combustor 16. Airflow (not shown in FIG. 1) from combustor 16 drives turbines 18 and 20, and turbine 20 drives fan assembly 12 by way of shaft 31.

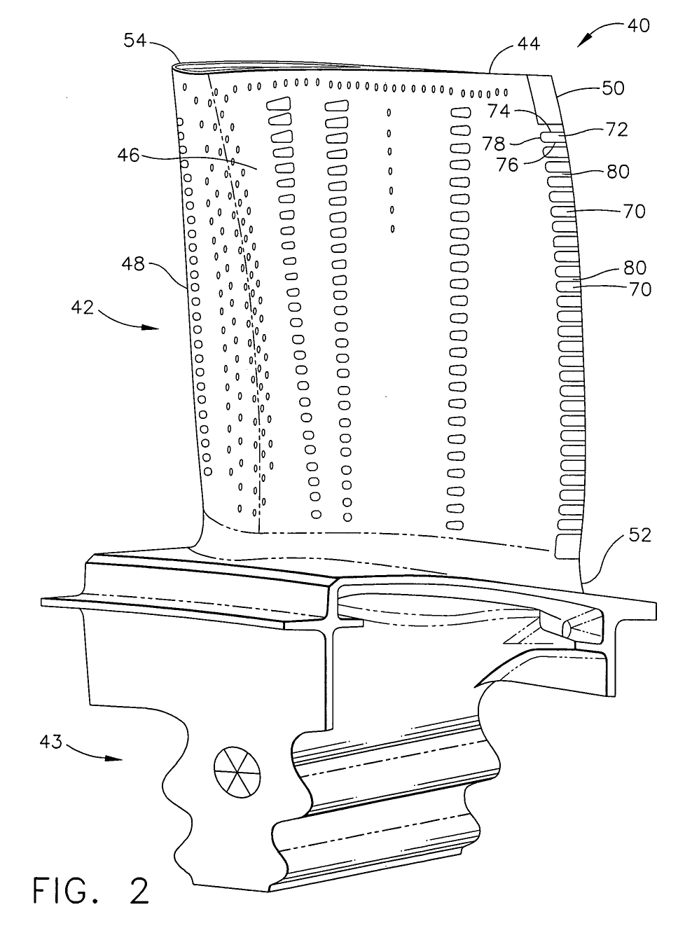

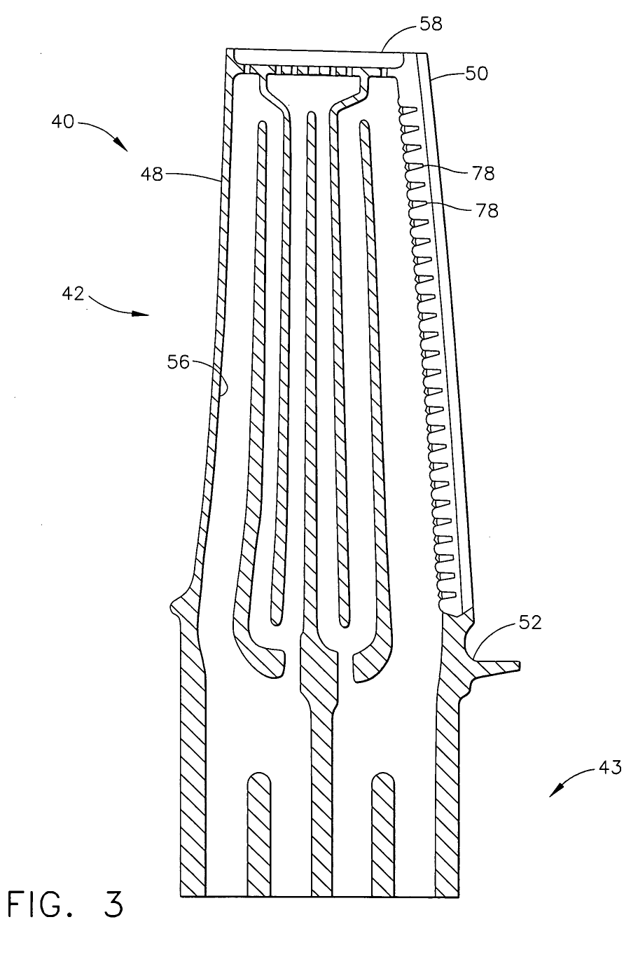

FIG. 2 is a perspective schematic illustration of a turbine rotor blade 40 that may be used with gas turbine engine 10 (shown in FIG. 1). FIG. 3 is an internal schematic illustration of turbine rotor blade 40. Referring to FIGS. 2 and 3, in an exemplary embodiment, a plurality of turbine rotor blades 40 form a turbine rotor blade stage (not shown) of gas turbine engine 10. Each rotor blade 40 includes a hollow airfoil 42 and an integral dovetail 43 used for mounting airfoil 42 to a rotor disk (not shown).

Airfoil 42 includes a first sidewall 44 and a second sidewall 46. First sidewall 44 is convex and defines a suction side of airfoil 42, and second sidewall 46 is concave and defines a pressure side of airfoil 42. Sidewalls 44 and 46 are connected at a leading edge 48 and at an axially-spaced trailing edge 50 of airfoil 42 that is downstream from leading edge 48.

First and second sidewalls 44 and 46, respectively, extend longitudinally or radially outward to span from a blade root 52 positioned adjacent dovetail 43 to a tip plate 54 which defines a radially outer boundary of an internal cooling chamber 56. Cooling chamber 56 is defined within airfoil 42 between sidewalls 44 and 46. In the exemplary embodiment, cooling chamber 56 includes a serpentine passage 58 cooled with compressor bleed air.

Cooling cavity 56 is in flow communication with a plurality of trailing edge slots 70 which extend longitudinally (axially) along trailing edge 50. Particularly, trailing edge slots 70 extend along pressure side wall 46 to trailing edge 50. Each trailing edge slot 70 includes a recessed wall 72 separated from pressure side wall 46 by a first sidewall 74 and a second sidewall 76. A cooling cavity exit opening 78 extends from cooling cavity 56 to each trailing edge slot 70 adjacent recessed wall 72. Each recessed wall 72 extends from trailing edge 50 to cooling cavity exit opening 78. A plurality of lands 80 separate each trailing edge slot 70 from an adjacent trailing edge slot 70. Sidewalls 74 and 76 extend from lands 80.

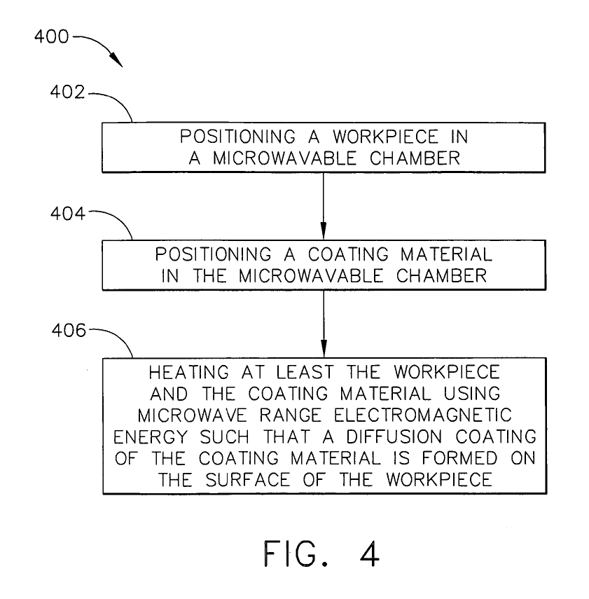

FIG. 4 is a flow chart of an exemplary method 400 of forming a metal coating on a surface of a workpiece, such as, but not limited to a turbine blade for a gas turbine engine. The method includes positioning 402 the turbine blade in a microwavable chamber, positioning 404 a coating material in the microwavable chamber, and heating 406 at least the turbine blade and the coating material using microwave range electromagnetic energy such that a diffusion coating of the coating material is vapor transferred to the surface of the turbine blade.

In the exemplary embodiment, the coating material includes a metal powder in a free form. In various alternative embodiments the coating material may be in the form of a pack, a tape or a slurry. Additionally, in one embodiment a powdered halide activator is also positioned in the microwavable chamber to facilitate the coating process.

The turbine blade, the coating material, and the activator are heated using electromagnetic energy in a frequency range of between approximately 0.915 Gigahertz and approximately 2.45 Gigahertz. The metal powder in the coating material and activator are heated directly by the microwave energy. The turbine blade is heated by conduction and/or convention from the coating material until it reaches an elevated temperature at which time it also begins to absorb microwave energy. The microwave energy is controlled such that a temperature ramp of the turbine blade, the coating material, and the activator is maintained at a predetermined constant rate or a predetermined temperature profile. The microwave source is configured to supply energy to maintain the temperature of the turbine blade, the coating material, and the activator at approximately 2100 degrees Fahrenheit for a predetermined dwell time. In the exemplary embodiment, the microwave source provides energy to maintain the temperature of the turbine blade, the coating material, and the activator at between approximately 1700 degrees Fahrenheit and approximately 2000 degrees Fahrenheit for a predetermined dwell time of between one and six hours.

During the coating process, the coating may be formed on an outer surface of the turbine blade and/or an inner passage of the blade. Furthermore, predetermined areas of the blade, such as a leading edge, trailing edge, or other portion of the blade may be covered using a non-activated tape that substantially prevents the area covered from being coated. To facilitate the coating process an atmosphere may be introduced into the chamber, such as, an inert atmosphere or a reducing atmosphere that may comprise at least one of argon and hydrogen. At the end of the predetermined dwell time the turbine blade, the coating material, and the activator are forced cooled or conventionally cooled to temperatures that are relatively safe for material handling.

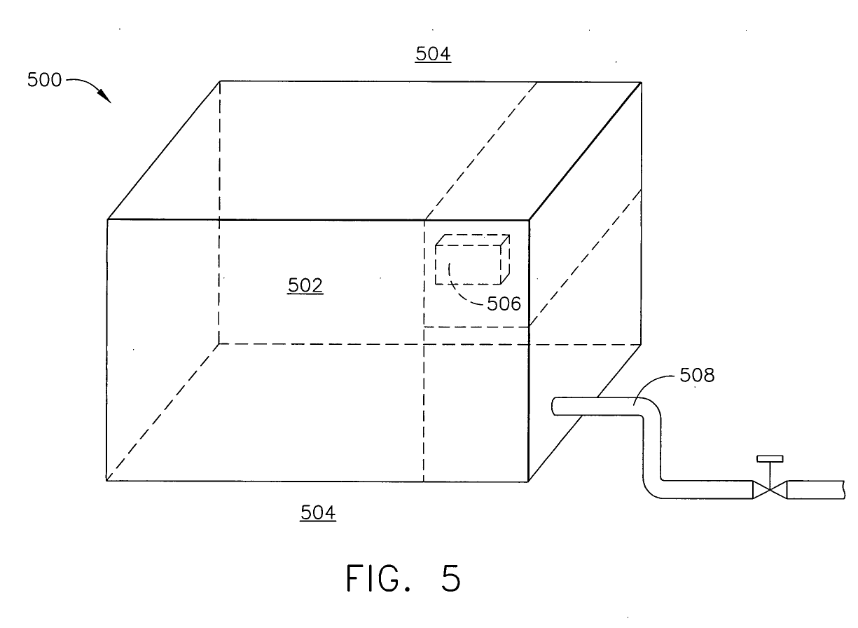

FIG. 5 is a perspective view of a diffusion deposition chamber 500 that may be used to perform the method illustrated in FIG. 4. Diffusion deposition chamber 500 includes an insulated microwavable chamber 502 configured to substantially prevent leakage of microwave energy from microwavable chamber 502 to an ambient space 504 surrounding microwavable chamber 502. Microwavable chamber 502 also includes a source of microwave energy 506 configured to heat a metallic object in the chamber substantially uniformly to a temperature of approximately 2100 degrees Fahrenheit. In the exemplary embodiment, source of microwave energy 506 is configured to generate electromagnetic energy in a frequency range of between approximately 0.915 Gigahertz and approximately 2.45 Gigahertz. Microwavable chamber 502 also includes a source 508 of a gas that provides an atmosphere in the chamber that is at least one of inert and reducing and may comprise argon and/or hydrogen.

The above-described diffusion deposition chamber is a cost-effective and highly reliable method and apparatus for heat gas turbine components to required coating temperature by means of efficient microwave absorption. The chamber permits heating the gas turbine components in a controlled manner and in a predetermined controllable atmosphere to facilitate obtaining a predictable substantially uniform aluminide or other metal coating. Accordingly, the diffusion deposition chamber facilitates coating of gas turbine engine components in a cost-effective and reliable manner.

Exemplary embodiments of diffusion deposition chamber components are described above in detail. The components are not limited to the specific embodiments described herein, but rather, components of each chamber may be utilized independently and separately from other components described herein. Each diffusion deposition chamber component can also be used in combination with other diffusion deposition chamber components.

What is claimed is:

1. A method of forming a metal coating on a surface of a workpiece comprising:
positioning the workpiece in a microwavable chamber;
positioning a coating material in the microwavable chamber; and
heating at least the workpiece and the coating material using microwave range electromagnetic energy such that a diffusion coating of the coating material is formed on the surface of the workpiece.

2. A method in accordance with claim 1 wherein the workpiece is a gas turbine component and wherein positioning the workpiece in a microwavable chamber comprises positioning the turbine component in the microwavable chamber.

3. A method in accordance with claim 1 wherein positioning a coating material in the microwavable chamber comprises positioning a coating material including a metal powder in at least one of a free form, a pack, a tape, and a slurry in the microwavable chamber.

4. A method in accordance with claim 1 wherein heating the workpiece and the coating material using electromagnetic energy in a frequency range of between approximately 0.915 Gigahertz and approximately 2.45 Gigahertz.

5. A method in accordance with claim 1 further comprising positioning a powdered halide activator in the microwavable chamber.

6. A method in accordance with claim 5 wherein heating the workpiece and the coating material using microwave range electromagnetic energy comprises heating the workpiece, the coating material, and the powdered halide activator using microwave range electromagnetic energy to a temperature of less then approximately 2100 degrees Fahrenheit such that a diffusion coating of the coating material is formed.

7. A method in accordance with claim 1 wherein heating the workpiece and the coating material using microwave range electromagnetic energy comprises heating the workpiece and the coating material using microwave range electromagnetic energy to a temperature of approximately 2100 degrees Fahrenheit such that a diffusion coating of the coating material is formed.

8. A method in accordance with claim 1 wherein heating at least the workpiece and the coating material using microwave range electromagnetic energy comprises heating the workpiece and the coating material using microwave range electromagnetic energy to a temperature of between approximately 1900 degrees Fahrenheit and approximately 2000 degrees Fahrenheit for between one to six hours.

9. A method in accordance with claim 1 wherein heating at least the workpiece and the coating material comprises forming the coating on at least one of an internal surface and an external surface of the workpiece.

10. A method in accordance with claim 1 further comprising selectively coating a predetermined localized area of the workpiece.

11. A method in accordance with claim 1 further comprising maintaining heating of the coated workpiece during a dwell period.

12. A method in accordance with claim 1 further comprising introducing an atmosphere that is at least one of inert and reducing.

13. A method in accordance with claim 1 further comprising introducing an atmosphere that includes at least one of argon and hydrogen.

14. A method of forming a metal coating on surfaces of a gas turbine component, the component having an outer surface and at least one internal passage, said method comprising:
positioning the component in a microwavable chamber;
positioning a coating material in the microwavable chamber;
introducing an atmosphere that is at least one of inert and reducing to the chamber; and
heating at least the component and the coating material using microwave range electromagnetic energy such that a diffusion coating of the coating material is formed on at least one of the outer surface and the at least one internal passage.

15. A method in accordance with claim 14 further comprising positioning a powdered halide activator in the microwavable chamber.

16. A method in accordance with claim 15 wherein heating comprises heating the component, the halide activator, and a coating material comprising aluminum such that an aluminide coating is deposited onto the component.

17. A method in accordance with claim 14 wherein heating comprises heating the component and the coating material using microwave range electromagnetic energy to a temperature of approximately 2100 degrees Fahrenheit.

18. A diffusion deposition chamber configured to form a metal coating on surfaces of a gas turbine component, the component having an outer surface and at least one internal passage, said diffusion deposition chamber comprising:
an insulated chamber configured to substantially prevent leakage of microwave energy from the chamber to an ambient space surrounding said chamber; and
a source of microwave energy configured to heat the component in the chamber substantially uniformly to a temperature of approximately 2100 degrees Fahrenheit.

19. A diffusion deposition chamber in accordance with claim 18 further comprising a source of a gas that provides an atmosphere in the chamber that is at least one of inert and reducing.

20. A diffusion deposition chamber in accordance with claim 18 wherein said source of microwave energy is configured to generate electromagnetic energy in a frequency range of between approximately 0.915 Gigahertz and approximately 2.45 Gigahertz.
